(19) United States
(12) Patent Application Publication
(10) Pub. No.: US 2006/0138646 A1
(43) Pub. Date: Jun. 29, 2006

(54) Low cost electromechanical devices manufactured from conductively doped resin-based materials

(76) Inventor: Thomas Aisenbrey, Littleton, CO (US)

Correspondence Address: DOUGLAS R. SCHNABEL, 1531 WEDGEWOOD PLACE, ESSEXVILLE, MI, 48732, US

(21) Appl. No.: 11/346,051

(22) Filed: Feb. 2, 2006

Related U.S. Application Data
(63) Continuation-in-part of application No. 10/877,092, filed on Jun. 25, 2004.
Application No. 10/877,092 is a continuation of application No. 10/309,429, filed on Dec. 4, 2002, now Pat. No. 6,870,516.
Application No. 10/309,429 is a continuation-in-part of application No. 10/075,778, filed on Feb. 14, 2002, now Pat. No. 6,741,221.
(60) Provisional application No. 60/649,219, filed on Feb. 2, 2005.
(60) Provisional application No. 60/317,808, filed on Sep. 7, 2001.
(60) Provisional application No. 60/269,414, filed on Feb. 16, 2001.
(60) Provisional application No. 60/268,822, filed on Feb. 15, 2001.

(51) Int. Cl. H01L 23/34

(52) U.S. Cl. 257/712

(57) ABSTRACT

Electromechanical devices are formed of a conductively doped resin-based material. The conductively doped resin-based material comprises micron conductive powder(s), conductive fiber(s), or a combination of conductive powder and conductive fibers in a base resin host. The percentage by weight of the conductive powder(s), conductive fiber(s), or a combination thereof is between about 20% and 50% of the weight of the conductively doped resin-based material. The micron conductive powders are metals or conductive non-metals or metal plated non-metals. The micron conductive fibers may be metal fiber or metal plated fiber. Further, the metal plated fiber may be formed by plating metal onto a metal fiber or by plating metal onto a non-metal fiber. Any platable fiber may be used as the core for a non-metal fiber. Superconductor metals may also be used as micron conductive fibers and/or as metal plating onto fibers in the present invention.

### RELATED PATENT APPLICATIONS

This patent application claims priority to the U.S. Provisional Patent Application 60/649,219 filed on Feb. 2, 2005, which is herein incorporated by reference in its entirety.

This patent application is a Continuation-in-Part of INT01-002CIPC, filed as U.S. patent application Ser. No. 10/877,092, filed on Jun. 25, 2004, which is a Continuation of INT01-002CIP, filed as U.S. patent application Ser. No. 10/309,429, filed on Dec. 4, 2002, now issued as U.S. Pat. No. 6,870,516, also incorporated by reference in its entirety, which is a Continuation-in-Part application of docket number INT01-002, filed as U.S. patent application Ser. No. 10/075,778, filed on Feb. 14, 2002, now issued as U.S. Pat. No. 6,741,221, which claimed priority to U.S. Provisional Patent Applications Ser. No. 60/317,808, filed on Sep. 7, 2001, Ser. No. 60/269,414, filed on Feb. 16, 2001, and Ser. No. 60/268,822, filed on Feb. 15, 2001, all of which are incorporated by reference in their entirety.

### BACKGROUND OF THE INVENTION

(1) Field of the Invention

This invention relates to electromechanical devices and, more particularly, to electromechanical devices molded of conductively doped resin-based materials comprising micron conductive powders, micron conductive fibers, or a combination thereof, substantially homogenized within a base resin when molded. This manufacturing process yields a conductive part or material usable within the EMF, thermal, acoustic, or electronic spectrum(s).

(2) Description of the Prior Art

Electromechanical devices, such as solenoids, relays, and electromagnets, find many applications. Electromechanical devices convert electrical energy into mechanical energy. Electric current is conducted through a coil, or winding, to generate a magnetic field. This magnetic field can then exert force onto a core structure or onto an external structure to cause mechanical movement, as in the case of a solenoid, or to cause the completion of another electrical circuit, as in the case of a relay. Electromechanical devices typically use metal wires for coils, windings, and connections. Cores are typically formed from stamped or forged metal, such as iron. Cases are typically stamped from sheet metal. Contacts are typically formed from molded and plated metal. Metal parts provide electrical conductivity, magnetic field concentration or reactivity, and mechanical strength. However, metal is relatively heavy—which can be a major problem for weight sensitive applications such as aeronautics. Metal manufacturing processes can also be expensive and design limiting. Finally, many metals are prone to corrosion if left exposed in harsh environments. Significant objects of the present invention are to describe a novel material that combines useful properties typical to metals with useful properties typical to resin-based materials and to apply this innovative material to electromagnetic devices to derive substantially improved performance.

Several prior art inventions relate to electromechanical devices and conductive resin-based materials. U.S. Patent Publication US 2004/0212469 A1 to Hasegawa et al teaches a rotary solenoid with a resin-molded body. U.S. Patent Publication US 2002/0118085 A1 to Hanson et al teaches an electrical solenoid for fluid controls that utilizes an elastomeric retaining device to eliminate the need for potting compound. U.S. Patent Publication US 2004/0227604 A1 to Mitteer et al teaches a solenoid with noise reduction capabilities that utilizes a magnet with a reverse polarity from that of the core, causing the center pole to repel from the bottom plate when the solenoid is de-energized. U.S. Patent Publication US 2001/0005166 A1 to Coulombier teaches a water resistant solenoid for water resistance at pressure depths. This invention encapsulates much of the solenoid in polytetrafluoroethylene.

U.S. Patent Publication US 2003/0030524 A1 to Sato et al teaches a solenoid for an electromagnetic valve to drive a valve member for switching flow paths. U.S. Patent Publication US 2004/0051069 A1 to Miyazoe teaches a solenoid valve with a terminal box for energizing an exciting coil. U.S. Patent Publication US 2004/0227119 A1 to Mills et al teaches an on/off solenoid control valve for controlling hydraulic functions of a transmission of a vehicle. U.S. Patent Publication US 2004/0000981 A1 to Thrush et al teaches an electromagnetic relay having noise dampening means, such as an elastomeric composition, a curable resin or other mechanical dampening composition or material disposed at a juncture between the relay armature and the movable spring in the relay to dampen acoustic noise. U.S. Patent Publication US 2002/0023768 A1 to Takami et al teaches a relay unit and a housing unit which combines a number of relay switches in a single package. U.S. Patent Publication US 2002/0036557 A1 to Nakamura et al teaches a relay of a simple structure capable of reliably making and breaking high load voltages.

### SUMMARY OF THE INVENTION

A principal object of the present invention is to provide an effective electromagnetic device.

A further object of the present invention is to provide a method to form an electromagnetic device.

A further object of the present invention is to provide an electromagnetic device molded of conductively doped resin-based materials.

A further object of the present invention is to provide a solenoid device comprising conductively doped resin-based material.

A further object of the present invention is to provide a relay device comprising conductively doped resin-based material.

A further object of the present invention is to provide an electromagnet device comprising conductively doped resin-based material.

A further object of the present invention is to provide a coil for an electromagnetic device comprising conductively doped resin-based material.

A further object of the present invention is to provide a core for an electromagnetic device comprising conductively doped resin-based material.

A further object of the present invention is to provide a case for an electromagnetic device comprising conductively doped resin-based material.

A further object of the present invention is to provide a contact for an electromagnetic device comprising conductively doped resin-based material.

A yet further object of the present invention is to provide an electromagnetic device molded of conductively doped resin-based material where the electrical, thermal, or acoustical characteristics can be altered or the visual characteristics can be altered by forming a metal layer over the conductively doped resin-based material.

A yet further object of the present invention is to provide methods to fabricate an electromagnetic device from a conductively doped resin-based material incorporating various forms of the material.

In accordance with the objects of this invention, an electromechanical device is achieved. The device comprises a conductive coil. A movable core is disposed within the conductive coil. The movable core moves when the conductive coil is energized. A case surrounds the conductive coil. The case comprises a conductively doped, resin-based material comprising conductive materials in a base resin host.

Also in accordance with the objects of this invention, an electromechanical device is achieved. The device comprises a conductive coil. A movable core is disposed within the conductive coil. The movable core moves when the conductive coil is energized. A case surrounds the conductive coil. The case comprises a conductively doped, resin-based material comprising conductive materials in a base resin host. The percent by weight of the conductive materials is between 20% and 50% of the total weight of the conductively doped resin-based material.

Also in accordance with the objects of this invention, an electromechanical device is achieved. The device comprises a conductive coil. A movable core is disposed within the conductive coil. The movable core moves when the conductive coil is energized. A case surrounds the conductive coil. The case comprises a conductively doped, resin-based material comprising micron conductive fiber in a base resin host.

### BRIEF DESCRIPTION OF THE DRAWINGS

In the accompanying drawings forming a material part of this description, there is shown:

FIG. 1 illustrates an embodiment of a pull-type solenoid comprising a conductively doped resin-based material.

FIG. 2 illustrates a first preferred embodiment of a conductively doped resin-based material wherein the conductive materials comprise a powder.

FIG. 3 illustrates a second preferred embodiment of a conductively doped resin-based material wherein the conductive materials comprise micron conductive fibers.

FIG. 4 illustrates a third preferred embodiment of a conductively doped resin-based material wherein the conductive materials comprise both conductive powder and micron conductive fibers.

FIGS. 5a and 5b illustrate a fourth preferred embodiment wherein conductive fabric-like materials are formed from the conductively doped resin-based material.

FIGS. 6a and 6b illustrate, in simplified schematic form, an injection molding apparatus and an extrusion molding apparatus that may be used to mold electromechanical devices of a conductively doped resin-based material.

FIG. 7 illustrates an embodiment of a push-type solenoid comprising a conductively doped resin-based material.

FIG. 8 illustrates an embodiment of a relay formed of a conductively doped resin-based material.

FIG. 9 illustrates an embodiment of a rotary-type solenoid formed of a conductively doped resin-based material.

FIG. 10 illustrates an embodiment of an electromagnet formed of a conductively doped resin-based material.

### DESCRIPTION OF THE PREFERRED EMBODIMENTS

This invention relates to electromechanical devices molded of conductively doped resin-based materials comprising micron conductive powders, micron conductive fibers, or a combination thereof, substantially homogenized within a base resin when molded.

The conductively doped resin-based materials of the invention are base resins doped with conductive materials to convert the base resin from an insulator to a conductor. The base resin provides structural integrity to the molded part. The doping material, such as micron conductive fibers, micron conductive powders, or a combination thereof, is substantially homogenized within the resin during the molding process. The resulting conductively doped resin-based material provides electrical, thermal, and acoustical continuity.

The conductively doped resin-based materials can be molded, extruded or the like to provide almost any desired shape or size. The molded conductively doped resin-based materials can also be cut, stamped, or vacuumed formed from an injection molded or extruded sheet or bar stock, over-molded, laminated, milled or the like to provide the desired shape and size. The thermal, electrical, and acoustical continuity and/or conductivity characteristics of articles or parts fabricated using conductively doped resin-based materials depend on the composition of the conductively doped resin-based materials. The type of base resin, the type of doping material, and the relative percentage of doping material incorporated into the base resin can be adjusted to achieve the desired structural, electrical, or other physical characteristics of the molded material. The selected materials used to fabricate the articles or devices are substantially homogenized together using molding techniques and or methods such as injection molding, over-molding, insert molding, compression molding, thermo-set, protrusion, extrusion, calendaring, or the like. Characteristics related to 2D, 3D, 4D, and 5D designs, molding and electrical characteristics, include the physical and electrical advantages that can be achieved during the molding process of the actual parts and the molecular polymer physics associated within the conductive networks within the molded part(s) or formed material(s).

In the conductively doped resin-based material, electrons travel from point to point, following the path of least resistance. Most resin-based materials are insulators and represent a high resistance to electron passage. The doping of the conductive loading into the resin-based material alters the inherent resistance of the polymers. At a threshold concentration of conductive loading, the resistance through the combined mass is lowered enough to allow electron movement. Speed of electron movement depends on conductive doping concentration and material makeup, that is, the separation between the conductive doping particles. Increasing conductive loading content reduces interparticle separation distance, and, at a critical distance known as the percolation point, resistance decreases dramatically and electrons move rapidly.

Resistivity is a material property that depends on the atomic bonding and on the microstructure of the material. The atomic microstructure material properties within the conductively doped resin-based material are altered when molded into a structure. A substantially homogenized conductive microstructure of delocalized valance electrons is created within the valance and conduction bands of the molecules. This microstructure provides sufficient charge carriers within the molded matrix structure. As a result, a low density, low resistivity, lightweight, durable, resin based polymer microstructure material is achieved. This material exhibits conductivity comparable to that of highly conductive metals such as silver, copper or aluminum, while maintaining the superior structural characteristics found in many plastics and rubbers or other structural resin based materials.

Conductively doped resin-based materials lower the cost of materials and of the design and manufacturing processes needed for fabrication of molded articles while maintaining close manufacturing tolerances. The molded articles can be manufactured into infinite shapes and sizes using conventional forming methods such as injection molding, over-molding, compression molding, thermoset molding, or extrusion, calendaring, or the like. The conductively doped resin-based materials, when molded, typically but not exclusively produce a desirable usable range of resistivity of less than about 5 to more than about 25 ohms per square, but other resistivities can be achieved by varying the dopant(s), the doping parameters and/or the base resin selection(s).

The conductively doped resin-based materials comprise micron conductive powders, micron conductive fibers, or any combination thereof, which are substantially homogenized together within the base resin, during the molding process, yielding an easy to produce low cost, electrical, thermal, and acoustical performing, close tolerance manufactured part or circuit. The resulting molded article comprises a three dimensional, continuous capillary network of conductive doping particles contained and or bonding within the polymer matrix. Exemplary micron conductive powders include carbons, graphites, amines, eeonomers, or the like, and/or of metal powders such as nickel, copper, silver, aluminum, nichrome, or plated or the like. The use of carbons or other forms of powders such as graphite(s) etc. can create additional low level electron exchange and, when used in combination with micron conductive fibers, creates a micron filler element within the micron conductive network of fiber(s) producing further electrical conductivity as well as acting as a lubricant for the molding equipment. Carbon nano-tubes may be added to the conductively doped resin-based material. The addition of conductive powder to the micron conductive fiber doping may improve the electrical continuity on the surface of the molded part to offset any skinning effect that occurs during molding.

The micron conductive fibers may be metal fiber or metal plated fiber. Further, the metal plated fiber may be formed by plating metal onto a metal fiber or by plating metal onto a non-metal fiber. Exemplary metal fibers include, but are not limited to, stainless steel fiber, copper fiber, nickel fiber, silver fiber, aluminum fiber, nichrome fiber, or the like, or combinations thereof. Exemplary metal plating materials include, but are not limited to, copper, nickel, cobalt, silver, gold, palladium, platinum, ruthenium, rhodium, and nichrome, and alloys of thereof. Any platable fiber may be used as the core for a non-metal fiber. Exemplary non-metal fibers include, but are not limited to, carbon, graphite, polyester, basalt, melamine, man-made and naturally-occurring materials, and the like. In addition, superconductor metals, such as titanium, nickel, niobium, and zirconium, and alloys of titanium, nickel, niobium, and zirconium may also be used as micron conductive fibers and/or as metal plating onto fibers in the present invention.

Where micron fiber is combined with base resin, the micron fiber may be pretreated to improve performance. According to one embodiment of the present invention, conductive or non-conductive powders are leached into the fibers prior to extrusion. In other embodiments, the fibers are subjected to any or several chemical modifications in order to improve the fibers interfacial properties. Fiber modification processes include, but are not limited to: chemically inert coupling agents; gas plasma treatment; anodizing; mercerization; peroxide treatment; benzoylation; or other chemical or polymer treatments.

Chemically inert coupling agents are materials that are molecularly bonded onto the surface of metal and or other fibers to provide surface coupling, mechanical interlocking, inter diffusion and adsorption and surface reaction for later bonding and wetting within the resin-based material. This chemically inert coupling agent does not react with the resin-based material. An exemplary chemically inert coupling agent is silane. In a silane treatment, silicon-based molecules from the silane bond to the surface of metal fibers to form a silicon layer. The silicon layer bonds well with the subsequently extruded resin-based material yet does not react with the resin-based material. As an additional feature during a silane treatment, oxane bonds with any water molecules on the fiber surface to thereby eliminate water from the fiber strands. Silane, amino, and silane-amino are three exemplary pre-extrusion treatments for forming chemically inert coupling agents on the fiber.

In a gas plasma treatment, the surfaces of the metal fibers are etched at atomic depths to re-engineer the surface. Cold temperature gas plasma sources, such as oxygen and ammonia, are useful for performing a surface etch prior to extrusion. In one embodiment of the present invention, gas plasma treatment is first performed to etch the surfaces of the fiber strands. A silane bath coating is then performed to form a chemically inert silicon-based film onto the fiber strands. In another embodiment, metal fiber is anodized to form a metal oxide over the fiber. The fiber modification processes described herein are useful for improving interfacial adhesion, improving wetting during homogenization, and/or reducing oxide growth (when compared to non-treated fiber). Pretreatment fiber modification also reduces levels of particle dust, fines, and fiber release during subsequent capsule sectioning, cutting or vacuum line feeding.

The resin-based structural material may be any polymer resin or combination of compatible polymer resins. Nonconductive resins or inherently conductive resins may be used as the structural material. Conjugated polymer resins, complex polymer resins, and/or inherently conductive resins may be used as the structural material. The dielectric properties of the resin-based material will have a direct effect upon the final electrical performance of the conductively doped resin-based material. Many different dielectric properties are possible depending on the chemical makeup and/or arrangement, such as linking, cross-linking or the like, of the polymer, co-polymer, monomer, ter-polymer, or homo-polymer material. Structural material can be, here given as examples and not as an exhaustive list, polymer resins produced by GE PLASTICS, Pittsfield, Mass., a range of other plastics produced by GE PLASTICS, Pittsfield, Mass., a range of other plastics produced by other manufacturers, silicones produced by GE SILICONES, Waterford, N.Y., or other flexible resin-based rubber compounds produced by other manufacturers.

The resin-based structural material doped with micron conductive powders, micron conductive fibers, or in combination thereof can be molded, using conventional molding methods such as injection molding or over-molding, or extrusion to create desired shapes and sizes. The molded conductively doped resin-based materials can also be stamped, cut or milled as desired to form create the desired shapes and form factor(s). The doping composition and directionality associated with the micron conductors within the doped base resins can affect the electrical and structural characteristics of the articles and can be precisely controlled by mold designs, gating and or protrusion design(s) and or during the molding process itself. In addition, the resin base can be selected to obtain the desired thermal characteristics such as very high melting point or specific thermal conductivity.

A resin-based sandwich laminate could also be fabricated with random or continuous webbed micron stainless steel fibers or other conductive fibers, forming a cloth like material. The webbed conductive fiber can be laminated or the like to materials such as Teflon, Polyesters, or any resin-based flexible or solid material(s), which when discretely designed in fiber content(s), orientation(s) and shape(s), will produce a very highly conductive flexible cloth-like material. Such a cloth-like material could also be used in forming articles that could be embedded in a person's clothing as well as other resin materials such as rubber(s) or plastic(s). When using conductive fibers as a webbed conductor as part of a laminate or cloth-like material, the fibers may have diameters of between about 3 and 12 microns, typically between about 8 and 12 microns or in the range of about 10 microns, with length(s) that can be seamless or overlapping.

The conductively doped resin-based material may also be formed into a prepreg laminate, cloth, or webbing. A laminate, cloth, or webbing of the conductively doped resin-based material is first homogenized with a resin-based material. In various embodiments, the conductively doped resin-based material is dipped, coated, sprayed, and/or extruded with resin-based material to cause the laminate, cloth, or webbing to adhere together in a prepreg grouping that is easy to handle. This prepreg is placed, or laid up, onto a form and is then heated to form a permanent bond. In another embodiment, the prepreg is laid up onto the impregnating resin while the resin is still wet and is then cured by heating or other means. In another embodiment, the wet lay-up is performed by laminating the conductively doped resin-based prepreg over a honeycomb structure. In another embodiment, the honeycomb structure is made from conductively doped, resin-based material. In yet another embodiment, a wet prepreg is formed by spraying, dipping, or coating the conductively doped resin-based material laminate, cloth, or webbing in high temperature capable paint.

Prior art carbon fiber and resin-based composites are found to display unpredictable points of failure. In carbon fiber systems there is little if any elongation of the structure. By comparison, in the present invention, the conductively doped resin-based material, even if formed with carbon fiber or metal plated carbon fiber, displays greater strength of the mechanical structure due to the substantial homogenization of the fiber created by the moldable capsules. As a result a structure formed of the conductively doped resin-based material of the present invention will maintain structurally even if crushed while a comparable carbon fiber composite will break into pieces.

The conductively doped resin-based material of the present invention can be made resistant to corrosion and/or metal electrolysis by selecting micron conductive fiber and/or micron conductive powder dopants and base resins that are resistant to corrosion and/or metal electrolysis. For example, if a corrosion/electrolysis resistant base resin is combined with fibers/powders or in combination of such as stainless steel fiber, inert chemical treated coupling agent warding against corrosive fibers such as copper, silver and gold and or carbon fibers/powders, then corrosion and/or metal electrolysis resistant conductively doped resin-based material is achieved. Another additional and important feature of the present invention is that the conductively doped resin-based material of the present invention may be made flame retardant. Selection of a flame-retardant (FR) base resin material allows the resulting product to exhibit flame retardant capability. This is especially important in applications as described herein.

The substantially homogeneous mixing of micron conductive fiber and/or micron conductive powder and base resin described in the present invention may also be described as doping. That is, the substantially homogeneous mixing transforms a typically non-conductive base resin material into a conductive material. This process is analogous to the doping process whereby a semiconductor material, such as silicon, can be converted into a conductive material through the introduction of donor/acceptor ions as is well known in the art of semiconductor devices. Therefore, the present invention uses the term doping to mean converting a typically non-conductive base resin material into a conductive material through the substantially homogeneous mixing of micron conductive fiber and/or micron conductive powder within a base resin.

As an additional and important feature of the present invention, the molded conductor doped resin-based material exhibits excellent thermal dissipation characteristics. Therefore, articles manufactured from the molded conductor doped resin-based material can provide added thermal dissipation capabilities to the application. For example, heat can be dissipated from electrical devices physically and/or electrically connected to an article of the present invention.

As a significant advantage of the present invention, articles constructed of the conductively doped resin-based material can be easily interfaced to an electrical circuit or grounded. In one embodiment, a wire can be attached to conductively doped resin-based articles via a screw that is fastened to the article. For example, a simple sheet-metal type, self tapping screw can, when fastened to the material, can achieve excellent electrical connectivity via the conductive matrix of the conductively doped resin-based material. To facilitate this approach a boss may be molded as part of the conductively doped resin-based material to accommodate such a screw. Alternatively, if a solderable screw material, such as copper, is used, then a wire can be soldered to the screw is embedded into the conductively doped resin-based material. In another embodiment, the conductively doped resin-based material is partly or completely plated with a metal layer. The metal layer forms excellent electrical conductivity with the conductive matrix. A connection of this metal layer to another circuit or to ground is then made. For example, if the metal layer is solderable, then a soldered connection may be made between the article and a grounding wire.

Where a metal layer is formed over the surface of the conductively doped resin-based material, any of several techniques may be used to form this metal layer. This metal layer may be used for visual enhancement of the molded conductively doped resin-based material article or to otherwise alter performance properties. Well-known techniques, such as electroless metal plating, electro plating, electrolytic metal plating, sputtering, metal vapor deposition, metallic painting, or the like, may be applied to the formation of this metal layer. If metal plating is used, then the resin-based structural material of the conductively doped, resin-based material is one that can be metal plated. There are many of the polymer resins that can be plated with metal layers. For example, GE Plastics, SUPEC, VALOX, ULTEM, CYCOLAC, UGIKRAL, STYRON, CYCOLOY are a few resin-based materials that can be metal plated. Electroless plating is typically a multiple-stage chemical process where, for example, a thin copper layer is first deposited to form a conductive layer. This conductive layer is then used as an electrode for the subsequent plating of a thicker metal layer.

A typical metal deposition process for forming a metal layer onto the conductively doped resin-based material is vacuum metallization. Vacuum metallization is the process where a metal layer, such as aluminum, is deposited on the conductively doped resin-based material inside a vacuum chamber. In a metallic painting process, metal particles, such as silver, copper, or nickel, or the like, are dispersed in an acrylic, vinyl, epoxy, or urethane binder. Most resin-based materials accept and hold paint well, and automatic spraying systems apply coating with consistency. In addition, the excellent conductivity of the conductively doped resin-based material of the present invention facilitates the use of extremely efficient, electrostatic painting techniques.

The conductively doped resin-based materials can be contacted in any of several ways. In one embodiment, a pin is embedded into the conductively doped resin-based material by insert molding, ultrasonic welding, pressing, or other means. A connection with a metal wire can easily be made to this pin and results in excellent contact to the conductively doped resin-based material conductive matrix. In another embodiment, a hole is formed in to the conductively doped resin-based material either during the molding process or by a subsequent process step such as drilling, punching, or the like. A pin is then placed into the hole and is then ultrasonically welded to form a permanent mechanical and electrical contact. In yet another embodiment, a pin or a wire is soldered to the conductively doped resin-based material. In this case, a hole is formed in the conductively doped resin-based material either during the molding operation or by drilling, stamping, punching, or the like. A solderable layer is then formed in the hole. The solderable layer is preferably formed by metal plating. A conductor is placed into the hole and then mechanically and electrically bonded by point, wave, or reflow soldered.

Another method to provide connectivity to the conductively doped resin-based material is through the application of a solderable ink film to the surface. One exemplary solderable ink is a combination of copper and solder particles in an epoxy resin binder. The resulting mixture is an active, screen-printable and dispensable material. During curing, the solder reflows to coat and to connect the copper particles and to thereby form a cured surface that is directly solderable without the need for additional plating or other processing steps. Any solderable material may then be mechanically and/or electrically attached, via soldering, to the conductively doped resin-based material at the location of the applied solderable ink. Many other types of solderable inks can be used to provide this solderable surface onto the conductively doped resin-based material of the present invention. Another exemplary embodiment of a solderable ink is a mixture of one or more metal powder systems with a reactive organic medium. This type of ink material is converted to solderable pure metal during a low temperature cure without any organic binders or alloying elements.

A ferromagnetic conductively doped resin-based material may be formed of the present invention to create a magnetic or magnetizable form of the material. Ferromagnetic micron conductive fibers and/or ferromagnetic conductive powders are substantially homogenized with the base resin. Ferrite materials and/or rare earth magnetic materials are added as a conductive doping to the base resin. With the substantially homogeneous mixing of the ferromagnetic micron conductive fibers and/or micron conductive powders, the ferromagnetic conductively doped resin-based material is able to produce an excellent low cost, low weight, high aspect ratio magnetize-able item. The magnets and magnetic devices of the present invention can be magnetized during or after the molding process. Adjusting the doping levels and or dopants of ferromagnetic micron conductive fibers and/or ferromagnetic micron conductive powders that are homogenized within the base resin can control the magnetic strength of the magnets and magnetic devices. By increasing the aspect ratio of the ferromagnetic doping, the strength of the magnet or magnetic devices can be substantially increased. The substantially homogenous mixing of the conductive fibers/powders or in combinations there of allows for a substantial amount of dopants to be added to the base re sin without causing the structural integrity of the item to decline mechanically. The ferromagnetic conductively doped resin-based magnets display outstanding physical properties of the base resin, including flexibility, moldability, strength, and resistance to environmental corrosion, along with superior magnetic ability. In addition, the unique ferromagnetic conductively doped resin-based material facilitates formation of items that exhibit superior thermal and electrical conductivity as well as magnetism.

A high aspect ratio magnet is easily achieved through the use of ferromagnetic conductive micron fiber or through the combination of ferromagnetic micron powder with conductive micron fiber. The use of micron conductive fiber allows for molding articles with a high aspect ratio of conductive fibers/powders or combinations there of in a cross sectional area. If a ferromagnetic micron fiber is used, then this high aspect ratio translates into a high quality magnetic article. Alternatively, if a ferromagnetic micron powder is combined with micron conductive fiber, then the magnetic effect of the powder is effectively spread throughout the molded article via the network of conductive fiber such that an effective high aspect ratio molded magnetic article is achieved. The ferromagnetic conductively doped resin-based material may be magnetized, after molding, by exposing the molded article to a strong magnetic field. Alternatively, a strong magnetic field may be used to magnetize the ferromagnetic conductively doped resin-based material during the molding process.

The ferromagnetic conductively doped is in the form of fiber, powder, or a combination of fiber and powder. The micron conductive powder may be metal fiber or metal plated fiber or powders. If metal plated fiber is used, then the core fiber is a platable material and may be metal or non-metal. Exemplary ferromagnetic conductive fiber materials include ferrite, or ceramic, materials as nickel zinc, manganese zinc, and combinations of iron, boron, and strontium, and the like. In addition, rare earth elements, such as neodymium and samarium, typified by neodymium-iron-boron, samarium-cobalt, and the like, are useful ferromagnetic conductive fiber materials. Exemplary ferromagnetic micron powder leached onto the conductive fibers include ferrite, or ceramic, materials as nickel zinc, manganese zinc, and combinations of iron, boron, and strontium, and the like. In addition, rare earth elements, such as neodymium and samarium, typified by neodymium-iron-boron, samarium-cobalt, and the like, are useful ferromagnetic conductive powder materials. A ferromagnetic conductive doping may be combined with a non-ferromagnetic conductive doping to form a conductively doped resin-based material that combines excellent conductive qualities with magnetic capabilities.

In the present invention, conductively doped resin-based material is applied to the formation of electromechanical devices, such as solenoids, relays, and electromagnets. The conductively doped resin-based material offers significant advantages of reduced weight, corrosion resistance, and ease of manufacture, while providing excellent electrical and thermal conductivity, acoustical performance, and capability over the electromagnetic spectrum.

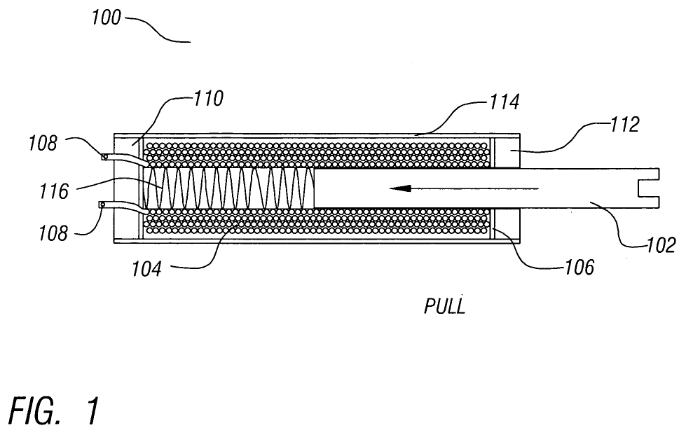

Referring now to FIG. 1, an embodiment of an electromechanical device of the present invention is illustrated. A pull-type solenoid 100 is shown. The solenoid 100 comprises the conductively doped resin-based material of the present invention. Any component, or several components, of the solenoid 100 may comprise the conductively doped resin-based material of the present invention. In various embodiments, plungers 102, conductors 104, bobbins 106, connectors 108, backstops 110, front plates 112, cases 114, and/or springs 116 are formed of conductively doped resin-based materials.

A pull-type solenoid has a coil around a cylinder and a moveable core that is drawn into the center of the coil when a current is applied. When current is shut off a spring forces the core back into the ready position. Prior art coils are made of metal wire, cores are made from iron, and cylinders are typically formed of a combination of glass filled nylon and brass in order to help to reduce friction. Electro-less nickel plating or other low friction coatings are also applied to the plunger in order to reduce the amount of friction and increase the life of the solenoid.

In one embodiment of the present invention, a plunger 102 for a solenoid 100 comprises the conductively doped resin-based material. In another embodiment of a conductively doped resin-based plunger 102, a ferrite alloy is selected as the micron conductive fiber and/or micron conductive powder filler to enhance the magnetic properties. Other conductive doping materials having substantial magnetic reactivity may be used in other embodiments. In one embodiment, the plunger 102 is simply extruded of the conductively doped resin-based material. In another embodiment, an outer layer of nickel is plated onto the conductively doped resin-based plunger 102. In yet another embodiment the plunger 102 is extruded and a non-metal low friction coating is applied. The plunger 102 comprising the conductively doped resin-based material has the mechanical advantage of weighing considerably less than a typical iron core plunger 102. A solenoid 100, thus formed, is therefore able to produce the same amount of electromechanical motion with less energy consumption.

In one embodiment a conductor coil 104 of a solenoid 100 comprises the conductively doped resin-based material of the present invention. The conductor coil 104 is formed by extruding a long conductive thread-like strand of the conductively doped resin-based material and then winding this strand onto a bobbin 106. In another embodiment the conductor coil 104 is a metal wire wound onto a conductively doped resin-based material bobbin 106. In another embodiment, conductively doped resin-based material is extruded into fine film sheets. These film sheets are then wrapped around a bobbin 106 to form a coil 104.

In another embodiment connectors 108 are formed of the conductively doped resin-based material of the present invention. The connectors 108 are electrically connected to the ends of s conductor coil 104 and act as the terminal connection for the power supply and/or control circuits. In one embodiment, the connectors 108 are co-molded with a coil 104 and both connectors 108 and coil 104 are formed of conductively doped resin-based material. In another embodiment, connectors 108 are over-molded onto a conductively doped resin-based material coil 104 or onto a wire coil 104.

In another embodiment, a case 114, backstop 110, or front plate 112 of a solenoid 100 comprise the conductively doped resin-based material of the present invention. The case 114, the backstop 110, and the front plate 112 serve as protective covers for a solenoid 100. By forming a protective cover of a solenoid from conductively doped resin-based material, the solenoid is shielded from unwanted electromagnetic interference. The backstop 110 and the case 114 are shown as two separate items in the drawing, however it is understood that they could just as easily be formed as one unit. The formation of protective cover elements 114, 110, and 112 from conductively doped resin-based materials provides cost savings and less complex manufacture when compared to prior art cases that are made by sheet metal forming.

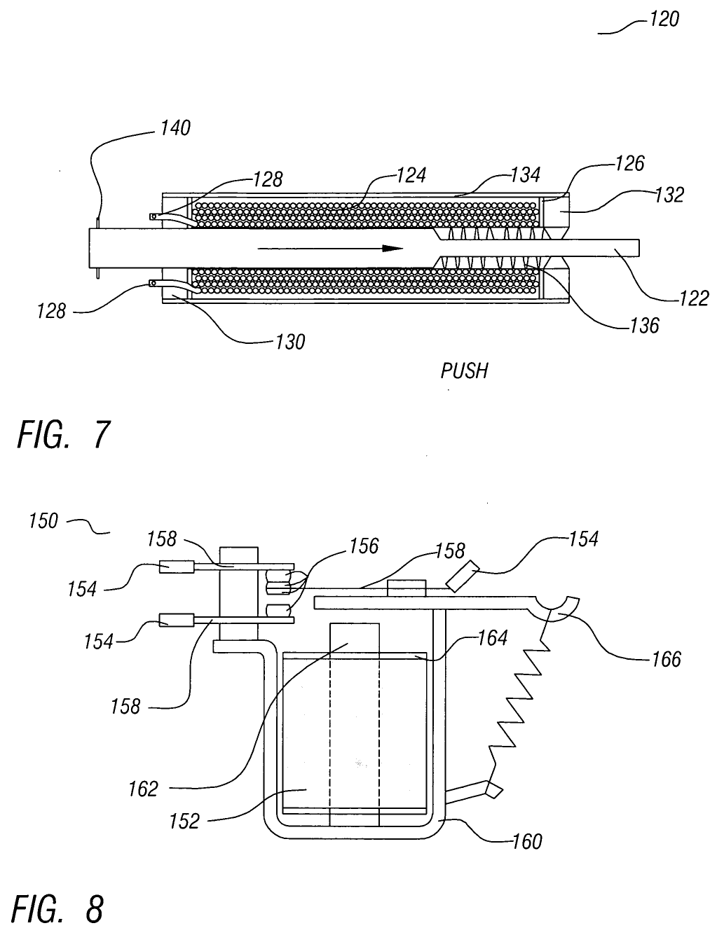

Referring now to FIG. 7, another embodiment of the present invention is illustrated. A push-type solenoid 120 is shown. The solenoid 120 comprises the conductively doped resin-based material of the present invention. Any component, or several components, of the solenoid 120 may comprise the conductively doped resin-based material of the present invention. In various embodiments, plungers 122, conductors 124, bobbins 126, connectors 128, backstops 130, front plates 132, cases 134, and/or springs 136 are formed of conductively doped resin-based materials.

A push-type solenoid has a coil around a cylinder and a moveable iron core that is drawn into the center of the coil when a current is applied. When the current is shut off a spring 136 forces the plunger back into the ready position. Prior art coils are made of metal wire, cores are made from iron, and cylinders are typically formed of a combination of glass filled nylon and brass in order to help to reduce friction. Electro-less nickel plating or other low friction coatings are also applied to the plunger in order to reduce the amount of friction and increase the life of the solenoid.

In one embodiment, a plunger 122 for a solenoid 120 comprises the conductively doped resin-based material. In another embodiment of a conductively doped resin-based plunger 122, a ferrite alloy is selected as the micron conductive fiber and/or micron conductive powder filler to enhance the magnetic properties. Other conductive doping materials having substantial magnetic reactivity are useful in other embodiments. In one embodiment, the plunger 122 is simply extruded of the conductively doped resin-based material. In another embodiment, an outer layer of nickel is plated onto the plunger 122. In yet another embodiment the plunger 122 is extruded and a non-metal low friction coating is applied. The plunger 122 comprising the conductively doped resin-based material has the mechanical advantage of weighing considerably less than a typical iron core plunger. The solenoid 120, thus formed, is therefore able to produce the same amount of electromechanical motion with less energy consumption.

In one embodiment a conductor coil 124 of a solenoid 120 comprises the conductively doped resin-based material of the present invention. The conductor coil 124 is formed by extruding a long conductive thread-like strand of the conductively doped resin-based material and then winding this strand onto the bobbin 126. In another embodiment the conductor coil is a metal wire wound onto a conductively doped resin-based material bobbin 126. In another embodiment, conductively doped resin-based material is extruded into fine film sheets. These film sheets are then wrapped around a bobbin 126 to form a coil 124.

In another preferred embodiment connectors 128 are formed of the conductively doped resin-based material of the present invention. The connectors 128 are electrically connected to the ends of the conductor coil 124 and act as a terminal connection for the power supply and/or control circuits. In one embodiment, the connectors 128 are co-molded with a coil 124 and are both connectors 128 and coil 124 are formed of conductively doped resin-based material. In another embodiment, connectors 128 are over-molded onto a conductively doped resin-based material coil 124 where the coil 124 or onto a wire coil 124.

In another embodiment, a case 134, backstop 130, retainer clip 140, or front plate 132 of a solenoid 120 comprise the conductively doped resin-based material of the present invention. The case 134, the backstop 130, and the front plate 132 serve as protective cover for the solenoid 120. By forming a protective cover of a solenoid from conductively doped resin-based material, the solenoid is shielded from unwanted electromagnetic interference. The backstop 130 and the case 134 are shown as two separate items in the drawing, however it is understood that they could just as easily be formed as one unit. The formation of protective cover elements 134, 130, and 132 and retainer clip 140 from conductively doped resin-based materials provides cost savings and less complex manufacture when compared to prior art cases that are made by sheet metal forming.

Referring now to FIG. 8, another embodiment of the present invention is illustrated. A relay 150 is shown. The relay 150 comprises the conductively doped resin-based material of the present invention. In various embodiments, the connectors 154, core 162, coil 152, bobbin 164, connector arm 158, pivot arm 166, contact points 156, and/or case 160 are formed of conductively doped resin-based materials.

A typical relay construction utilizes a wire coiled around an iron core to form an electromagnet. When the electromagnet is energized, a magnetic field forces a toggle arm onto a contact point to make an electrical connection. When the current is shut off a spring forces the toggle arm back into the ready position to break the connection. In prior art relays, contact points, toggle arms, coils, and the like are typically constructed of metal.

In one embodiment of the present invention, a core 162 comprises conductively doped resin-based material. In one embodiment, a ferrite alloy is selected as the micron conductive fiber and/or micron conductive powder filler to enhance the magnetic properties. Other conductive loading materials having substantial magnetic reactivity are useful in other embodiments. In one embodiment, the core 162 is simply extruded of the conductively doped resin-based material. In another embodiment, an outer layer of metal plating and/or metal coating is formed onto a molded conductively doped, resin-based material core 162. A core 162 comprising the conductively doped resin-based material weighs considerably less than a typical iron core 162 while still retaining the needed magnetic properties.

In one embodiment the relay coil 152 comprises conductively doped resin-based material of the present invention. In one case the coil 152 may be formed by extruding a long conductive thread-like strand of the conductively doped resin-based material and winding this strand onto the bobbin 164. In another case the coil 152 may be formed by winding a metal wire onto a conductively doped resin-based material bobbin 164. In another instance the conductively doped resin-based material is first extruded into fine film sheets. These film sheets are then wrapped around a bobbin 164 to form a coil 152.

In one embodiment connectors 154 for the relay 150 are formed of the conductively doped resin-based material of the present invention. The connectors 154 are electrically connected to the ends of the connector arms 158 and act as the terminal connection to a control circuit, not shown. In one embodiment, the connectors 154, and the connector arms, 158 are formed entirely of the conductively doped resin-based material of the present invention. In another embodiment, the connectors 154 are over-molded onto the connector arms 158 where the connector arms 158 are conductively doped resin-based materials or where the connector arms 158 are metal.

In another embodiment, the relay case 160 and toggle arm 166 comprise conductively doped resin-based material of the present invention. The case 160 and the toggle arm 166 serve as a protective cover for the relay 150. This protective cover, formed of the conductively doped resin-based material, helps to shield the solenoid from unwanted electromagnetic interference. The formation of the protective cover 160 and 166 from conductively doped resin-based materials provides cost savings and less complex manufacture when compared to sheet metal forming.

In another embodiment relay contact points 156 are formed of the conductively doped resin-based material of the present invention. The contact points 156 are electrically connected to the ends of the connector arms 158 opposite the connectors 154. In one embodiment, the contact points 156, the connector arms 158, and the connectors 154 are formed entirely of the conductively doped resin-based material of the present invention. In another embodiment, the contact points 156 are over-molded onto the connector arms 158 where the connector arms 158 are conductively doped resin-based materials or where the connector arms 158 are metal. In another embodiment the contact points are formed of the conductively doped resin-based material and then metal plated and/or metal coated.

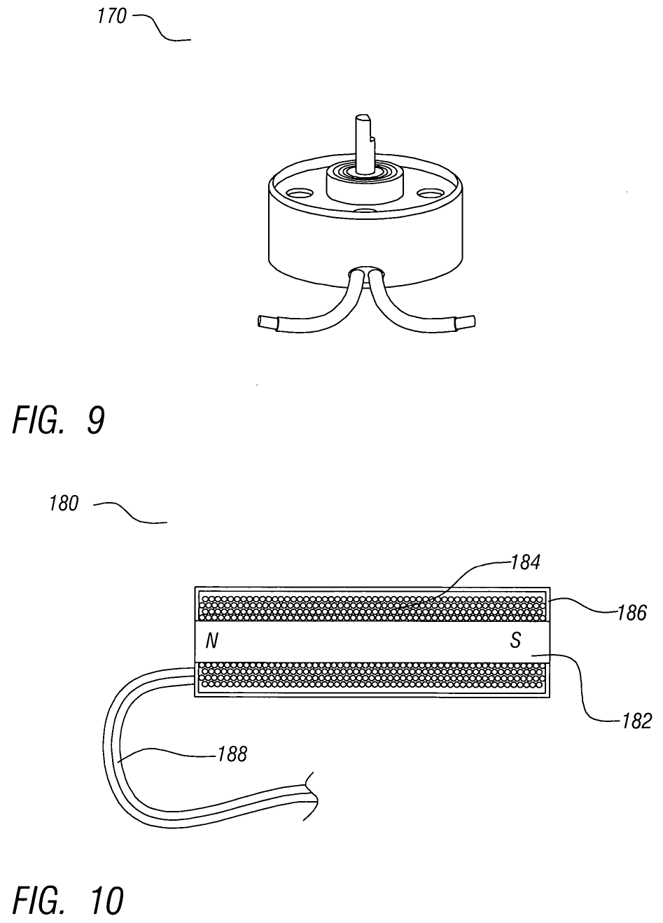

Referring now to FIG. 9, another embodiment of the present invention is illustrated. A rotary solenoid 170 is shown. The rotary solenoid 170 comprises the conductively doped resin-based material of the present invention. In the present invention, any component, or several components, of the rotary solenoid 170 comprises the conductively doped resin-based material of the present invention. In various embodiments, the plunger, conductor, bobbin, connectors, backstop, front plate, shaft, and/or the outer case are formed of the conductively doped resin-based material.

The rotary solenoid utilizes inclined machined grooves to allow motion from a linear solenoid to be converted into rotational motion. The angle of rotation and the axial of deflection are governed by the incline of the grooves. The rotary solenoid illustrated is representative of numerous types of rotary solenoids that can benefit from the properties of the conductively doped resin-based material of the present invention.

Referring now to FIG. 10, another embodiment of the present invention is illustrated. An electromagnet 180 is shown. The electromagnet 180 comprises the conductively doped resin-based material of the present invention. In the present invention, any component, or several components, of the electromagnet 180 comprises the conductively doped resin-based material of the present invention. In various embodiments, the core 182, conductor coil 184, outer case 186 and/or the ribbon conductor 188 comprise the conductively doped resin-based material.

Typical electromagnet construction utilizes a wire coil that is wrapped around an iron core. When energized, the current-carrying wire induces a magnetic field. The magnetic field is increased when the number of turns around the iron core increase or the amount of current in the wire increases. When the electrical current is turned off, the electromagnet returns to its previous state with only a small magnetic field remaining which is know as residual magnetism.

In one embodiment, the electromagnet core 182 comprises the conductively doped resin-based material of the present invention. In one embodiment, a ferrite alloy is selected as the micron conductive fiber and/or micron conductive powder filler to enhance the magnetic properties. Other conductive loading materials having substantial magnetic reactivity are useful in other embodiments. In one embodiment, the core 182 is simply extruded from the conductively doped resin-based material. In another embodiment, an outer layer of metal plating and/or metal coating is formed on the core 182. The core 182 comprising the conductively doped resin-based material weighs considerably less than a typical iron core 182 while still retaining the magnetic properties needed.

In one embodiment the electromagnet coil 184 comprises the conductively doped resin-based material of the present invention. The coil 184 may be formed by extruding a long conductive thread-like strand of the conductively doped resin-based material and winding this strand onto the core 182. In another embodiment the coil 184 is formed by winding a metal wire onto a conductively doped resin-based material core 182. In another embodiment, the conductively doped resin-based material is extruded into fine film sheets. These film sheets are then wrapped around the core 182 to form the coil 184.

In one embodiment, the electromagnet case 186 comprises the conductively doped resin-based material of the present invention. The case 186 serves as the protective cover for the electromagnet 180. This protective cover, formed of the conductively doped resin-based material, helps to shield the electromagnet. The formation of the case 186 from conductively doped resin-based materials provides cost savings and less complex manufacture when compared to sheet metal forming.

In one embodiment, a ribbon conductor 188 comprises the conductively doped resin-based material of the present invention. In the embodiment the ribbon conductor 188 is formed by co-extruding the conductively doped resin-based material with an outer insulating layer of a non conductive resin-based material. The ribbon connector 188 is electrically connected to the coil and serves to connect the electromagnet to the power source. In one embodiment, the ribbon conductor 188 and the coil 184 are formed entirely of the conductively doped resin-based material of the present invention. In another embodiment, the ribbon conductor 188 is over-molded onto a coil connector (not shown) where the coil connector is conductively doped resin-based materials or where the connectors are metal.

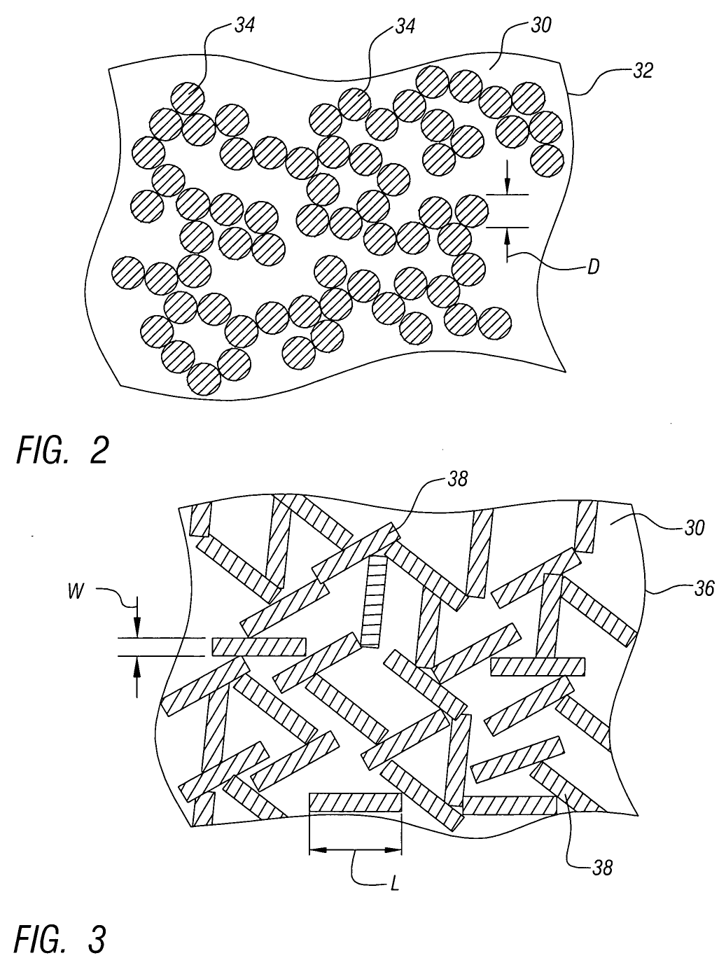

The conductively doped resin-based material typically comprises a micron powder(s) of conductor particles and/or in combination of micron fiber(s) substantially homogenized within a base resin host. FIG. 2 shows a cross section view of an example of conductively doped resin-based material 32 having powder of conductor particles 34 in a base resin host 30. In this example the diameter D of the conductor particles 34 in the powder is between about 3 and 12 microns.

FIG. 3 shows a cross section view of an example of conductively doped resin-based material 36 having conductor fibers 38 in a base resin host 30. The conductor fibers 38 have a diameter of between about 3 and 12 microns, typically in the range of 10 microns or between about 8 and 12 microns, and a length of between about 2 and 14 millimeters. The micron conductive fibers 38 may be metal fiber or metal plated fiber. Further, the metal plated fiber may be formed by plating metal onto a metal fiber or by plating metal onto a non-metal fiber. Exemplary metal fibers include, but are not limited to, stainless steel fiber, copper fiber, nickel fiber, silver fiber, aluminum fiber, nichrome fiber, or the like, or combinations thereof. Exemplary metal plating materials include, but are not limited to, copper, nickel, cobalt, silver, gold, palladium, platinum, ruthenium, rhodium, and nichrome, and alloys of thereof. Any platable fiber may be used as the core for a non-metal fiber. Exemplary non-metal fibers include, but are not limited to, carbon, graphite, polyester, basalt, man-made and naturally-occurring materials, and the like. In addition, superconductor metals, such as titanium, nickel, niobium, and zirconium, and alloys of titanium, nickel, niobium, and zirconium may also be used as micron conductive fibers and/or as metal plating onto fibers in the present invention.

These conductor particles and/or fibers are substantially homogenized within a base resin. As previously mentioned, the conductively doped resin-based materials have a sheet resistance of less than about 5 to more than about 25 ohms per square, though other values can be achieved by varying the doping parameters and/or resin selection. To realize this sheet resistance the weight of the conductor material comprises between about 20% and about 50% of the total weight of the conductively doped resin-based material. More preferably, the weight of the conductive material comprises between about 20% and about 40% of the total weight of the conductively doped resin-based material. More preferably yet, the weight of the conductive material comprises between about 25% and about 35% of the total weight of the conductively doped resin-based material. Still more preferably yet, the weight of the conductive material comprises about 30% of the total weight of the conductively doped resin-based material. Stainless Steel Fiber of 6-12 micron in diameter and lengths of 4-6 mm and comprising, by weight, about 30% of the total weight of the conductively doped resin-based material will produce a very highly conductive parameter, efficient within any EMF, thermal, acoustic, or electronic spectrum.

In yet another preferred embodiment of the present invention, the conductive doping is determined using a volume percentage. In a most preferred embodiment, the conductive doping comprises a volume of between about 4% and about 10% of the total volume of the conductively doped resin-based material. In a less preferred embodiment, the conductive doping comprises a volume of between about 1% and about 50% of the total volume of the conductively doped resin-based material though the properties of the base resin may be impacted by high percent volume doping.

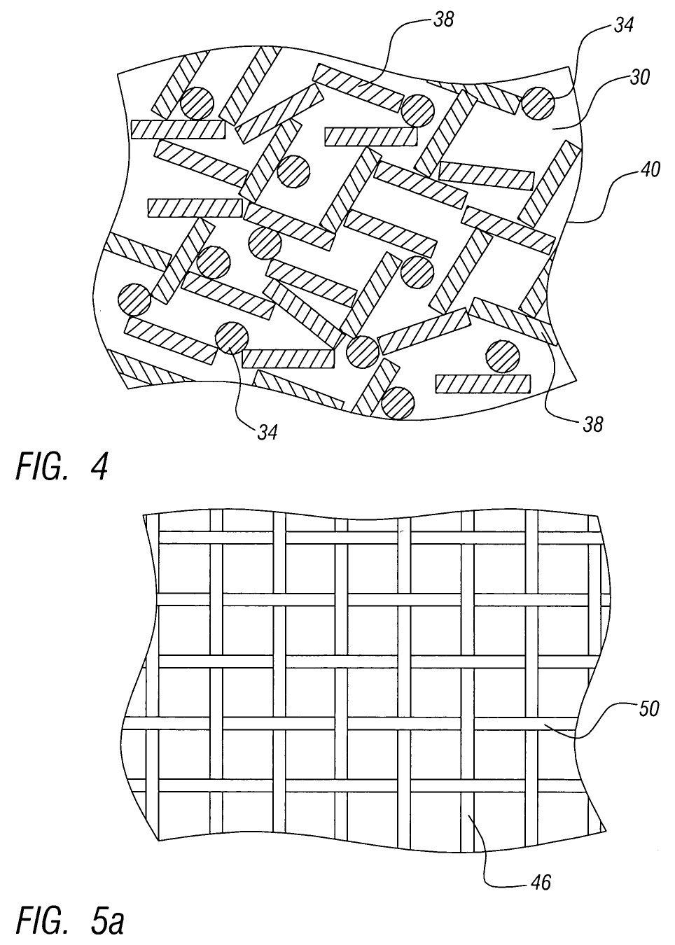

Referring now to FIG. 4, another preferred embodiment of the present invention is illustrated where the conductive materials comprise a combination of both conductive powders 34 and micron conductive fibers 38 substantially homogenized together within the resin base 30 during a molding process.

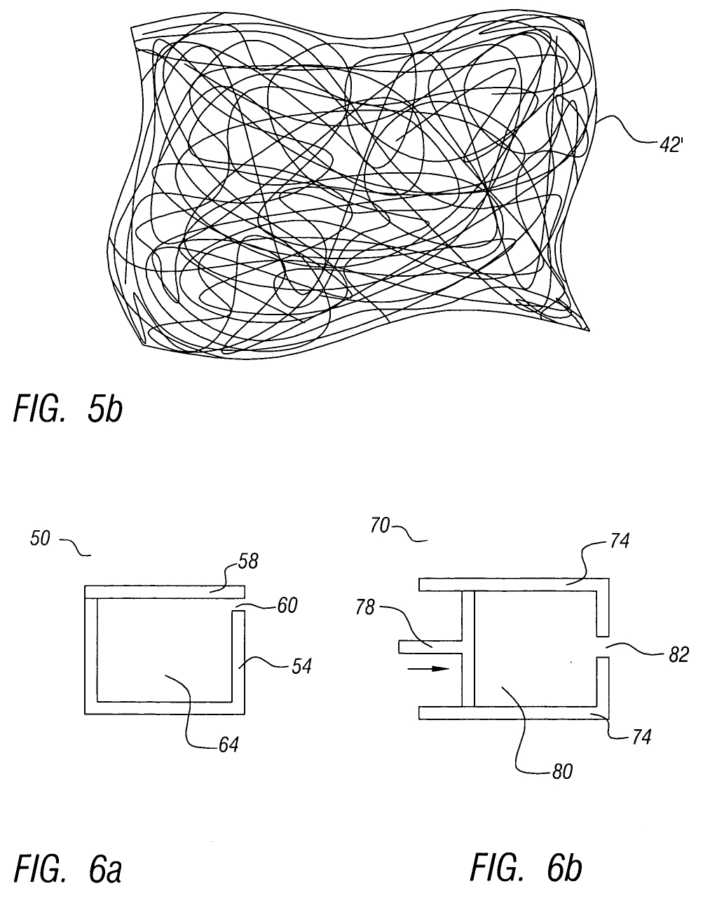

Referring now to FIGS. 5a and 5b, a preferred composition of the conductively doped, resin-based material is illustrated. The conductively doped resin-based material can be formed into fibers or textiles that are then woven or webbed into a conductive fabric. The conductively doped resin-based material is formed in strands that can be woven as shown. FIG. 5a shows a conductive fabric 42 where the fibers are woven together in a two-dimensional weave 46 and 50 of fibers or textiles. FIG. 5b shows a conductive fabric 42′ where the fibers are formed in a webbed arrangement. In the webbed arrangement, one or more continuous strands of the conductive fiber are nested in a random fashion. The resulting conductive fabrics or textiles 42, see FIG. 5a, and 42′, see FIG. 5b, can be made very thin, thick, rigid, flexible or in solid form(s).

Similarly, a conductive, but cloth-like, material can be formed using woven or webbed micron stainless steel fibers, or other micron conductive fibers. These woven or webbed conductive cloths could also be sandwich laminated to one or more layers of materials such as Polyester(s), Teflon(s), Kevlar(s) or any other desired resin-based material(s). This conductive fabric may then be cut into desired shapes and sizes.

Articles formed from conductively doped resin-based materials can be formed or molded in a number of different ways including injection molding, extrusion, calendaring, compression molding, thermoset molding, or chemically induced molding or forming. FIG. 6a shows a simplified schematic diagram of an injection mold showing a lower portion 54 and upper portion 58 of the mold 50. Conductively doped resin-based material is injected into the mold cavity 64 through an injection opening 60 and then the substantially homogenized conductive material cures by thermal reaction. The upper portion 58 and lower portion 54 of the mold are then separated or parted and the articles are removed.

FIG. 6b shows a simplified schematic diagram of an extruder 70 for forming articles using extrusion. Conductively doped resin-based material(s) is placed in the hopper 80 of the extrusion unit 74. A piston, screw, press or other means 78 is then used to force thermally molten, chemically-induced compression, or thermoset curing conductively doped resin-based material through an extrusion opening 82 which shapes the thermally molten curing or chemically induced cured conductively doped resin-based material to the desired shape. The conductively doped resin-based material is then fully cured by chemical reaction or thermal reaction to a hardened or pliable state and is ready for use. Thermoplastic or thermosetting resin-based materials and associated processes may be used in molding the conductively doped resin-based articles of the present invention.

The advantages of the present invention may now be summarized. An effective electromagnetic device is described. A method to form an electromagnetic device is described. An electromagnetic device may be molded of conductively doped resin-based materials. A solenoid device, a relay device, and an electromagnet device comprising conductively doped resin-based material are described. Coils, cores, cases, and contacts for an electromagnetic device comprising conductively doped resin-based material are described. The electrical, thermal, or acoustical characteristics of an electromagnetic device molded of conductively doped resin-based material can be altered or the visual characteristics can be altered by forming a metal layer over the conductively doped resin-based material. Methods to fabricate an electromagnetic device from a conductively doped resin-based material incorporating various forms of the material are described.

As shown in the preferred embodiments, the novel methods and devices of the present invention provide an effective and manufacturable alternative to the prior art.

While the invention has been particularly shown and described with reference to the preferred embodiments thereof, it will be understood by those skilled in the art that various changes in form and details may be made without departing from the scope of the invention.

What is claimed is:

1. An electromechanical device comprising:
a conductive coil;
a movable core disposed within said conductive coil wherein said movable core moves when said conductive coil is energized; and
a case surrounding said conductive coil wherein said case comprises a conductively doped, resin-based material comprising conductive materials in a base resin host.

2. The device according to claim 1 wherein the percent by weight of said conductive materials is between about 20% and about 50% of the total weight of said conductively doped resin-based material.

3. The device according to claim 1 wherein said conductive materials comprise micron conductive fiber.

4. The device according to claim 2 wherein said conductive materials further comprise conductive powder.

5. The device according to claim 1 wherein said conductive materials are metal.

6. The device according to claim 1 wherein said conductive materials are non-conductive materials with metal plating.

7. The device according to claim 1 wherein said conductive coil comprises said conductively doped resin-based material.

8. The device according to claim 7 wherein said conductive coil is formed from strips of said conductively doped resin-based material.

9. The device according to claim 1 wherein said core comprises said conductively doped resin-based material.

10. The device according to claim 9 wherein said core further comprises a ferromagnetic doping.

11. The device according to claim 1 further comprising conductive contacts that are connected depending on the position of said movable core.

12. An electromechanical device comprising:
a conductive coil;
a movable core disposed within said conductive coil wherein said movable core moves when said conductive coil is energized; and
a case surrounding said conductive coil wherein said case comprises a conductively doped, resin-based material comprising conductive materials in a base resin host wherein the percent by weight of said conductive materials is between 20% and 50% of the total weight of said conductively doped resin-based material.

13. The device according to claim 12 wherein said conductive materials are nickel plated carbon micron fiber, stainless steel micron fiber, copper micron fiber, silver micron fiber or combinations thereof.

14. The device according to claim 12 wherein said conductive materials comprise micron conductive fiber and conductive powder.

15. The device according to claim 14 wherein said conductive powder is nickel, copper, or silver.

16. The device according to claim 14 wherein said conductive powder is a non-metallic material with a metal plating.

17. The device according to claim 1 wherein said conductive coil comprises said conductively doped resin-based material.

18. The device according to claim 17 wherein said conductive coil is formed from strips of said conductively doped resin-based material.

19. The device according to claim 12 wherein said core comprises said conductively doped resin-based material.

20. The device according to claim 19 wherein said core further comprises a ferromagnetic doping.

21. The device according to claim 12 further comprising conductive contacts that are connected depending on the position of said movable core.

22. An electromechanical device comprising:
a conductive coil;
a movable core disposed within said conductive coil wherein said movable core moves when said conductive coil is energized; and
a case surrounding said conductive coil wherein said case comprises a conductively doped, resin-based material comprising micron conductive fiber in a base resin host.

23. The device according to claim 22 wherein said micron conductive fiber is stainless steel.

24. The device according to claim 23 further comprising conductive powder.

25. The device according to claim 22 wherein said micron conductive fiber has a diameter of between about 3 μm and about 12 μm and a length of between about 2 mm and about 14 mm.

26. The device according to claim 22 wherein said conductive coil comprises said conductively doped resin-based material.

27. The device according to claim 26 wherein said conductive coil is formed from strips of said conductively doped resin-based material.

28. The device according to claim 22 wherein said core comprises said conductively doped resin-based material.

29. The device according to claim 28 wherein said core further comprises a ferromagnetic doping.

30. The device according to claim 22 further comprising conductive contacts that are connected depending on the position of said movable core.
